(19) United States
(12) Patent Application Publication
(10) Pub. No.: US 2010/0284019 A1
(43) Pub. Date: Nov. 11, 2010

(54) SEMICONDUCTOR INTEGRATED OPTICAL DEVICE AND METHOD OF MAKING THE SAME

(75) Inventor: Chie Fukuda, Yokohama-shi (JP)

Correspondence Address: SMITH, GAMBRELL & RUSSELL, 1130 CONNECTICUT AVENUE, N.W., SUITE 1130, WASHINGTON, DC, 20036, US

(73) Assignee: Sumitomo Electric Industries, Ltd., Osaka (JP)

(21) Appl. No.: 12/775,617

(22) Filed: May 7, 2010

(30) Foreign Application Priority Data
May 11, 2009 (JP) P2009-114765

(51) Int. Cl. G01B 9/02; G02B 6/12; H01L 21/20; H01S 5/125; G02B 6/26

(52) U.S. Cl. 356/477; 385/14; 438/478; 372/50.121; 385/28; 257/E21.09

(57) ABSTRACT

A semiconductor integrated optical device includes a group III-V compound semiconductor substrate, a semiconductor optical device region, and an optical waveguide region. The semiconductor optical device region and the optical waveguide region are arranged on the group III-V compound semiconductor substrate. The semiconductor optical device region has a first optical waveguide made of group III-V compound semiconductor. The optical waveguide region has a second optical waveguide optically coupled with the first optical waveguide. The optical waveguide region further includes a silicon oxide layer. The silicon oxide layer is disposed between the group III-V compound semiconductor substrate and the second optical waveguide. The second optical waveguide is made of semiconductor which is different from the group III-V compound semiconductor.

### BACKGROUND OF THE INVENTION

1. Field of the Invention

The present invention relates to a semiconductor integrated optical device and a method of making the same.

2. Related Background Art

Japanese Unexamined Patent Application Publication No. 2007-164110 (hereinafter, referred to as “Patent Document 1”) discloses an integrated optical circuit in which a light emitting device or a light receiving device is mounted on a silicon substrate having an optical waveguide. According to this Patent Document 1, a method referred to as “epitaxial lift-off” is used for making the integrated optical circuit. This method includes steps of growing semiconductor layers on a wafer to make an optical device including the light emitting device or the light receiving device, protecting the optical device with a waxing compound, cutting the wafer to fowl the optical device chip, and arranging the optical device onto the silicon wafer having the optical waveguide.

Alexander W. Fang et al., “Electrically pumped hybrid AlGaInAs silicon evanescent laser”, OPTICS EXPRESS, Vol. 14, No. 20, pp. 9203-9210 (2006) (hereinafter, referred to as “Non-Patent Document 1”) discloses an optical device in which a semiconductor laser with an active layer made of AlGaInAs is mounted on an optical waveguide composed of silicon. AlGaInAs semiconductor is a III-V group compound semiconductor and is different from a IV group semiconductor such as silicon. The optical waveguide is formed on a silicon on insulator (SOI) substrate.

FIG. 24 is a plan view of the optical device described in Non-Patent Document 1. FIG. 25 is a cross-sectional view taken along the line XXV-XXV in FIG. 24. As illustrated in FIG. 24, the optical device 200 includes optical waveguides 202 on a SOI substrate 201. An array of semiconductor lasers 203 is arranged on the optical waveguides 202.

As illustrated in FIG. 25, the semiconductor laser array 203 includes an n-type InP/InGaAsP superlattice layer 205 and an n-type InP layer 206 formed on the layer 205. The n-type InP/InGaAsP superlattice layer 205 is attached on a silicon layer 204 of the SOI substrate 201. The semiconductor lasers in the array 203 each includes an AlGaInAs multiple quantum well (MQW) layer 207, a p-type AlGaInAs optical confinement layer 208, a p-type InP cladding layer 209, and a p-type InGaAs contact layer 210. These layers are stacked in sequence on the n-type InP layer 206 and constitute a mesa structure. An anode electrode 211 is disposed on the contact layer 210. A cathode electrode 212 is disposed on a region of the n-type InP layer 206 surrounding the mesa structure.

On the SOI substrate 201, a plurality of optical modulators 213 and an optical multiplexer 214 are further disposed. The optical modulators 213 are optically connected to the optical waveguides 202 respectively. The optical multiplexer 214 selects and outputs one light component among light components emitted from the semiconductor lasers 203 through the optical modulators 213.

### SUMMARY OF THE INVENTION

The integrated optical circuit described in the Patent Document 1 requires high-accuracy alignment (e.g. not exceeding 1 μm) between an optical waveguide and a light emitting device (or a light receiving device). As a result, the yield rate of producing integrated optical circuits is inevitably low. On the other hand, in the configuration described in the Non-Patent Document 1 (FIG. 25), the semiconductor lasers 203 are disposed on the optical waveguides 202. An optical axis of the optical waveguides 202 does not correspond to an optical axis of the semiconductor lasers 203 in the waveguiding direction. Therefore, the overlap region is small between the propagation modes (or optical fields) of the optical waveguides 202 and the emitting part of the semiconductor lasers 203 (multiple quantum well layer 207). This results in a low optical coupling efficiency between the optical waveguides 202 and the semiconductor lasers 203.

In an aspect of the present invention, a semiconductor integrated optical device comprises (1) a group III-V compound semiconductor substrate; (2) a semiconductor optical device region provided on the group III-V compound semiconductor substrate, the semiconductor optical device region having a first optical waveguide made of group III-V compound semiconductor; and (3) an optical waveguide region provided on the group III-V compound semiconductor substrate and extending along the semiconductor optical device region. The optical waveguide region has a second optical waveguide optically coupled with the first optical waveguide, and the second optical waveguide extends along a primary surface of the group III-V compound semiconductor substrate. The optical waveguide region further includes a silicon oxide layer for a lower cladding layer, the silicon oxide layer being provided between the group III-V compound semiconductor substrate and the second optical waveguide. Furthermore, the second optical waveguide is made of semiconductor which is different from the group III-V compound semiconductor.

The semiconductor integrated optical device of the present invention has a semiconductor optical device region and an optical waveguide region on a group III-V compound semiconductor substrate. The first optical waveguide of the semiconductor optical device region, which comprises group III-V compound semiconductor, can be formed on the substrate by crystal growth. On the other hand, a silicon oxide layer is provided between the second optical waveguide of the optical waveguide region and the substrate. The silicon oxide layer can be formed by deposition such as inductively-coupled plasma CVD (ICP-CVD). The overlying second optical waveguide can be fanned preferably by deposition of semiconductor different from the group III-V compound. For example, the semiconductor different from the group III-V compound is silicon.

Such a configuration enables precise alignment of the first optical waveguide with the second optical waveguide. The vertical positions of these optical waveguides can be adjusted accurately through control of thickness of the silicon oxide layer and semiconductor layers. The thickness of each layer is controlled accurately by determination of the time of deposition. The horizontal positions of these optical waveguides can be adjusted accurately through photolithographic formation of the first and second optical waveguides. Thus, the semiconductor integrated optical device of the present invention can exhibit an enhanced coupling efficiency between the semiconductor optical device region and the optical waveguide region.

In the semiconductor integrated optical device of the present invention, both of the semiconductor optical device region and optical waveguide region can be formed by growth or deposition of materials on the substrate. Since the alignment between the regions can be readily achieved, the yield rate of the resulting semiconductor integrated optical device can be improved.

In this semiconductor integrated optical device, the second optical waveguide may be made of silicon. Thus, compared to the second optical waveguide comprising group III-V compound semiconductor, the difference in refractive index between the second optical waveguide and the circumference of the waveguide is increased, so that the capability of the optical confinement is enhanced. Thus, the semiconductor integrated optical device can become smaller due to narrowed spacings between the second optical waveguides.

In this semiconductor integrated optical device, the optical waveguide region may comprise an upper cladding layer on the silicon oxide layer, the upper cladding layer covers the second optical waveguide, and the upper cladding layer may comprise at least one of silicon oxide and benzocyclobutene resin. Alternatively, the second optical waveguide may be exposed.

In this semiconductor integrated optical device, the silicon oxide layer may have a thickness in a range of 1.5 μm to 4 μm. The silicon oxide layer has a thickness greater than or equal to 1.5 μm. Therefore, propagating light can be effectively confined in the optical waveguide. However, if the thickness of the silicon oxide layer is greater than 4 μm, a warpage of the semiconductor substrate occurs by internal stress of the silicon oxide layer. Therefore, the silicon oxide layer having a thickness not greater than 4 μm can effectively suppress a warpage of the group III-V compound semiconductor substrate.

In this semiconductor integrated optical device, the semiconductor optical device region may comprise a DFB semiconductor laser. Furthermore, the semiconductor optical device region may comprise a plurality of DFB semiconductor lasers, and the DFB semiconductor lasers may have different laser emission wavelengths from one another. Such a configuration can readily produce a transmission device for a wavelength division multiplexing system.

In this semiconductor integrated optical device, the semiconductor optical device region may comprise a photodiode structure having a light-absorbing layer.

In this semiconductor integrated optical device, the optical waveguide region may comprise a multi-mode interference coupler which is optically coupled to the second optical waveguide. Alternatively, the optical waveguide region may comprise a wavelength multi/demultiplexer using a Mach-Zehnder interferometer, and the second optical waveguide may constitute the Mach-Zehnder interferometer.

Another aspect of the present invention is a method of making the semiconductor integrated optical device described above. This method comprises the steps of: (1) growing a group III-V compound semiconductor layer on the group III-V compound semiconductor substrate to form the first optical waveguide; (2) removing a part of the group III-V compound semiconductor layer to provide a space for the optical waveguide region; (3) depositing the silicon oxide layer in the space by inductively-coupled plasma CVD; and (4) forming the second optical waveguide on the silicon oxide layer.

By this method, the semiconductor integrated optical device according to an aspect of the present invention can be readily made. Through deposition of the silicon oxide layer by inductively coupled plasma CVD, the film stress of the silicon oxide layer can be controlled.

The silicon oxide layer may have a compressive internal stress in a range of 50 MPa to 500 MPa. In cases where the internal stress in the silicon oxide layer is a compressive stress greater than or equal to 50 MPa, flaking and cracking of the silicon oxide layer can be suppressed even if the silicon oxide layer is relatively thick, for example, greater than or equal to 2 μm thick. In cases where the internal stress in the silicon oxide layer is a compressive stress not greater than 500 MPa, a warp of the group III-V compound semiconductor substrate can be suppressed to enhance lithographic accuracy in a post-process.

The present invention will be more fully understood from the detailed description given hereinbelow and the accompanying drawings, which are given by way of illustration only and are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will be apparent to those skilled in the art from this detailed description.

### BRIEF DESCRIPTION OF THE DRAWINGS

FIGS. 1A and 1B are schematic views showing a semiconductor integrated optical device in a first embodiment of the present invention.

FIGS. 2A and 2B are cross-sectional views showing a semiconductor integrated optical device in the first embodiment.

FIG. 3 illustrates a typical laser output spectrum of a semiconductor integrated device used as a light source that emits four light components having different wavelengths simultaneously.

FIGS. 4A and 4B illustrate typical laser output spectra of a semiconductor integrated device used as a wavelength-switchable light source.

FIG. 5 is a flow chart showing steps of a method of making a semiconductor integrated optical device.

FIG. 6A is a cross-sectional view showing a method for manufacturing a semiconductor integrated optical device according to the first embodiment. FIG. 6B is a cross-sectional view showing a method for manufacturing a semiconductor integrated optical device, the step shown in FIG. 6B being performed after the step shown in FIG. 6A;

FIG. 7 is a cross-sectional view showing a method for manufacturing a semiconductor integrated optical device, the step shown in FIG. 7 being performed after the step shown in FIG. 6B.

FIG. 8A is a cross-sectional view showing a method for manufacturing a semiconductor integrated optical device, the step shown in FIG. 8A being performed after the step shown in FIG. 7. FIG. 8B is a cross-sectional view showing a method for manufacturing a semiconductor integrated optical device, the step shown in FIG. 8B being performed after the step shown in FIG. 8A.

FIG. 9 is a cross-sectional view showing a method for manufacturing a semiconductor integrated optical device, the step shown in FIG. 9 being performed after the step shown in FIG. 8B.

FIGS. 10A and 10B are schematic views showing a method for manufacturing a semiconductor integrated optical device, the step shown in FIGS. 10A and 10B being performed after the step shown in FIG. 9.

FIG. 11 is a cross-sectional view showing a method for manufacturing a semiconductor integrated optical device, the step shown in FIG. 11 being performed after the step shown in FIGS. 10A and 10B.

FIGS. 12A and 12B are schematic views showing a method for manufacturing a semiconductor integrated optical device, the step shown in FIGS. 12A and 12B being performed after the step shown in FIG. 11.

FIGS. 13A and 13B are schematic views showing a method for manufacturing a semiconductor integrated optical device, the step shown in FIGS. 13A and 13B being performed after the step shown in FIGS. 12A and 12B.

FIGS. 14A and 14B are schematic views showing a semiconductor integrated optical device in a second embodiment of the present invention.

FIGS. 15A and 15B are cross-sectional views showing a semiconductor integrated optical device in a second embodiment of the present invention.

FIG. 16 is a plan view showing a typical configuration of an optical directional coupler.

FIG. 17 is a graph showing the relation between wavelength and an optical loss of an optical multi/demultiplexer using a Mach-Zehnder interferometer.

FIG. 18 is a cross-sectional view showing a method for manufacturing a semiconductor integrated optical device according to the second embodiment.

FIG. 19A is a cross-sectional view showing a method for manufacturing a semiconductor integrated optical device, the step shown in FIG. 19A being performed after the step shown in FIG. 18. FIG. 19B is a cross-sectional view showing a method for manufacturing a semiconductor integrated optical device, the step shown in FIG. 19B being performed after the step shown in FIG. 19A.

FIGS. 20A and 20B are schematic views showing a method for manufacturing a semiconductor integrated optical device, the step shown in FIGS. 20A and 20B being performed after the step shown in FIG. 19B.

FIG. 21 is a cross-sectional view showing a method for manufacturing a semiconductor integrated optical device, the step shown in FIG. 21 being performed after the step shown in FIGS. 20A and 20B.

FIGS. 22A and 22B are schematic views showing a method for manufacturing a semiconductor integrated optical device, the step shown in FIGS. 22A and 22B being performed after the step shown in FIG. 21.

FIGS. 23A and 23B are schematic views showing a method for manufacturing a semiconductor integrated optical device, the step shown in FIGS. 23A and 23B being performed after the step shown in FIGS. 22A and 22B.

FIG. 24 is a plan view of the structure of the optical device described in the Non-Patent Document 1.

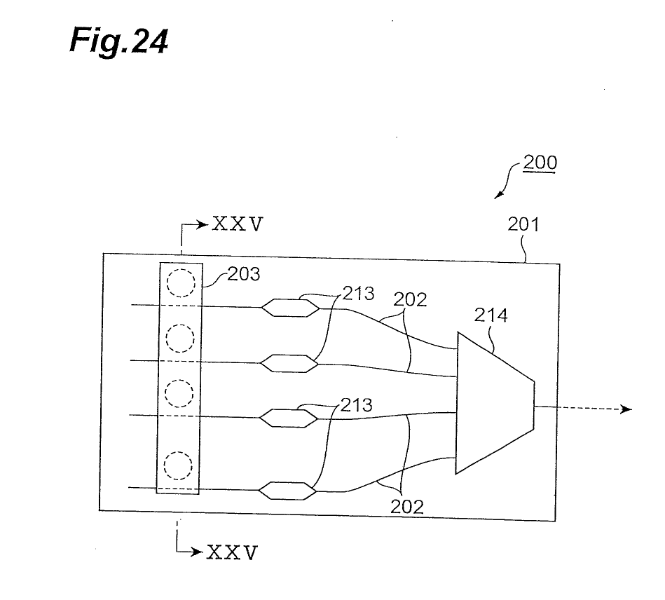

FIG. 25 is a cross-sectional view taken along the line XXV-XXV in FIG. 24.

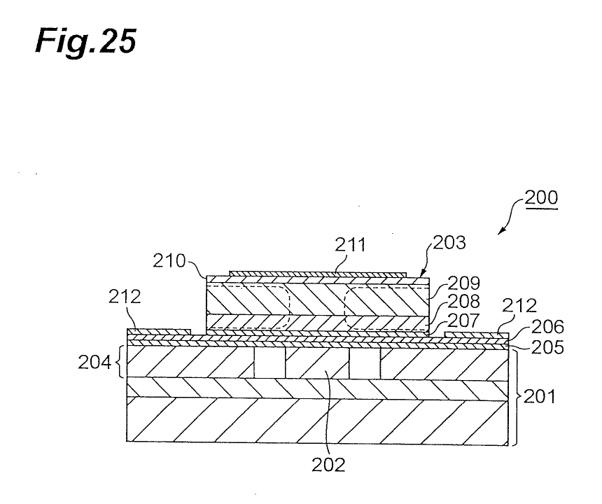

### DESCRIPTION OF THE PREFERRED EMBODIMENTS

The teaching of the present invention will be readily understood through the following detailed description with reference to the accompanying drawings shown as examples. Embodiments according to a semiconductor integrated optical device and a method of making the same according to the present invention will be described with reference to the accompanying drawings. The same elements are designated by the same reference numerals, if possible.

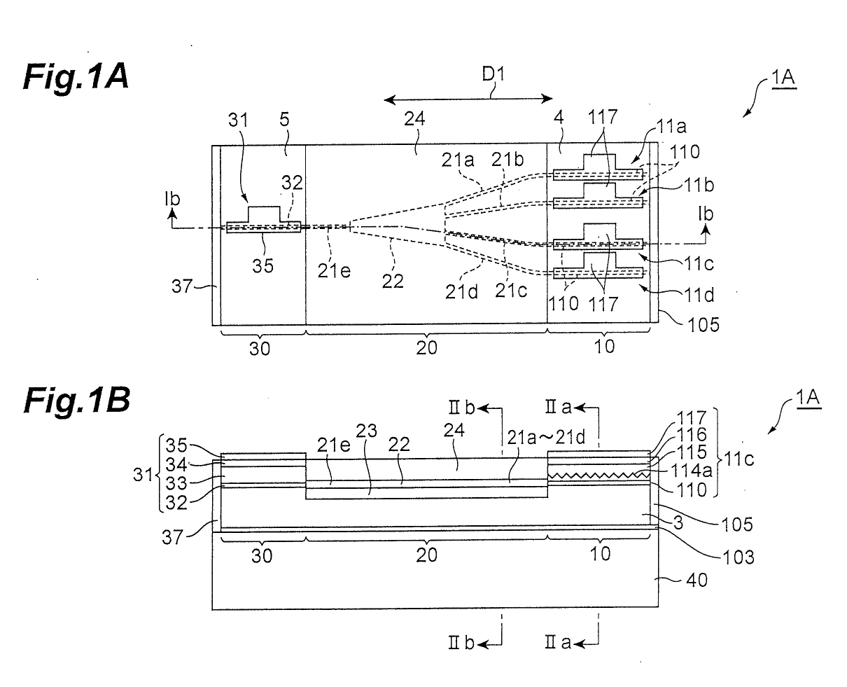

FIG. 1A is a plan view of a semiconductor integrated optical device in a first embodiment of the present invention. FIG. 1B is a cross-sectional view taken along the line Ib-Ib in FIG. 1A. The semiconductor integrated optical device 1A illustrated in FIGS. 1A and 1B comprises a semiconductor laser region 10, an optical waveguide region 20, and a light amplification region 30. The semiconductor laser region 10 has a plurality of DFB semiconductor lasers 11a to 11d. The optical waveguide region 20 has a plurality of optical waveguides 21a to 21e and a multi-mode interferometer (MMI) wavelength multi/demultiplexer 22 (hereinafter referred to as MMI coupler). The light amplification region 30 has a semiconductor optical amplifier (SOA) 31. The semiconductor laser region 10 and the light amplification region 30 are provided for semiconductor optical device regions in the present embodiment.

As illustrated in FIG. 1B, a semiconductor laser region 10, an optical waveguide region 20, and a light amplification region 30 are formed on a semiconductor substrate 3 and arranged in a waveguiding direction D1. Preferred lengths of the semiconductor laser region 10, the optical waveguide region 20, and the light amplification region 30 in the waveguiding direction D1 are 250 μm, 600 μm, and 150 μm, respectively. The semiconductor substrate 3 can be a group III-V compound semiconductor substrate in the present embodiment. The semiconductor substrate 3 is composed of first conductive type semiconductor such as n-type InP. The semiconductor substrate 3 functions as a lower cladding layer in the semiconductor laser region 10 and the light amplification region 30.

The semiconductor integrated optical device 1A is disposed on a cooling structure 40. The cooling structure 40 is composed of, for example, a pair of metal plates which functions as a heat sink, and a Peltier device which is disposed between the pair of metal plates and transfers heat. The cooling structure 40 keeps the semiconductor substrate 3 and a layered structure on the primary surface of the substrate 3 at constant temperature.

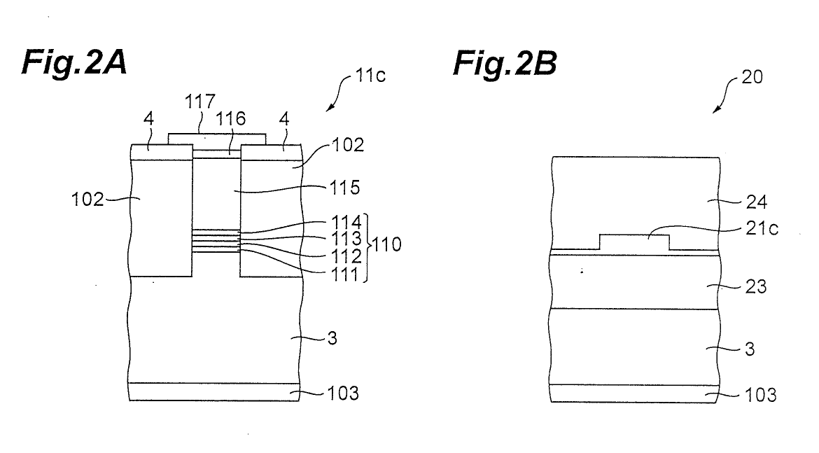

With reference to FIGS. 1A, 1B and 2A, a configuration of the semiconductor lasers 11a to 11d included in the semiconductor laser region 10 will be explained below. FIG. 2A is a cross-sectional view of the semiconductor laser region 10, taken along the line IIa-IIa in FIG. 1B. FIG. 2A illustrates a semiconductor laser 11c as a representative example among the semiconductor lasers 11a to 11d of the semiconductor laser region 10. The other semiconductor lasers 11a, 11b, and 11d have a similar structure as the semiconductor laser 11c. The cooling structure 40 is not depicted in FIG. 2A.

The semiconductor laser 11c includes a first optical waveguide 110, an upper cladding layer 115, and a contact layer 116. The optical waveguide 110 is disposed on the semiconductor substrate 3. The upper cladding layer 115 is disposed on the optical waveguide 110. The contact layer 116 is disposed on the upper cladding layer 115. The optical waveguide 110 is composed of material containing group III-V compound semiconductor which has a longer band gap wavelength or a smaller band gap energy compared with the semiconductor material of the semiconductor substrate 3. It is noted that a band gap wavelength λg exhibits emission wavelength due to interband transition determined by a band gap Eg of semiconductor. The band gap wavelength λg and the band gap Eg have the following relation. λg=1.24/Eg. The optical waveguide 110 extends along a primary surface of the semiconductor substrate 3. As illustrated in FIG. 2A, the optical waveguide 110 includes a lower optical confinement layer 111, an active layer 112, an upper optical confinement layer 113, and a diffraction grating layer 114. The lower optical confinement layer 111 is disposed on the semiconductor substrate 3. The active layer 112 is disposed on the lower optical confinement layer 111. The upper optical confinement layer 113 is disposed on the active layer 112. The diffraction grating layer 114 is disposed on the upper optical confinement layer 113.

In an embodiment, the lower optical confinement layer 111 and the upper optical confinement layer 113 are composed of undoped GaInAsP. The active layer 112 has a GaInAsP multiple quantum well (MQW) structure. The composition of the active layer 112 is adjusted so as to emit light having the 1.3 μm wavelength band or the 1.55 μm wavelength band. The diffraction grating layer 114, the upper cladding layer 115, and the contact layer 116 are composed of second conductive type group III-V compound semiconductor. For example, the diffraction grating layer 114 is composed of p-type GaInAsP, the upper cladding layer 115 is composed of p-type InP, and the contact layer 116 is composed of p-type GaInAs.

At the interface between the diffraction grating layer 114 and the upper cladding layer 115, a diffraction grating 114a is formed. The diffraction grating 114a has a periodic corrugation. The diffraction gratings of the semiconductor lasers 11a to 11d have different pitches of the corrugation from one another. Thus, the semiconductor lasers 11a to 11d have different lasing wavelengths which depend on the pitch of the corrugation.

As illustrated in FIG. 2A, a mesa stripe structure is formed on the semiconductor substrate 3. The mesa stripe structure includes the optical waveguide 110, the upper cladding layer 115, and the contact layer 116. The mesa stripe structure extends toward a predetermined waveguiding direction. The mesa stripe structure is formed by etching, and has a width suitable for light propagation with a single waveguide mode. The width of the mesa stripe structure in the direction intersecting the waveguiding direction is, for example, 1.8 μm. On both sides of the mesa stripe structure, semi-insulating regions 102 are disposed. The semi-insulating regions 102 are composed of semi-insulating or high-resistivity semiconductor such as InP doped with Fe. The semi-insulating regions 102 are disposed on the surface of the semiconductor substrate 3 to bury the both sides of the mesa stripe structure.

An anode electrode 117 is disposed on the contact layer 116. The anode electrode 117 is composed of, for example, Ti/Pt/Au. This structure produces ohmic contact between the anode electrode 117 and the contact layer 116. A cathode electrode 103 is disposed on the back surface of the semiconductor substrate 3. The cathode electrode 103 is composed of, for example, AuGe. This structure produces ohmic contact between the cathode electrode 103 and the semiconductor substrate 3. The optical waveguide 110 is supplied with electric current from the anode electrode 117 to the cathode electrode 103.

The upper surface of the semiconductor laser region 10 other than the region of the anode electrode 117 is protected by an insulating film 4. The insulating film 4 is composed of, for example, SiO₂.

As illustrated in FIGS. 1A and 1B, a high reflection (HR) film 105 is disposed on the end facet of the semiconductor laser region 10 in the waveguiding direction D1. The reflectivity of the HR film 105 is, for example, 90%.

With reference to FIGS. 1A, 1B and 2B, the configuration of an optical waveguide region 20 will be explained below. FIG. 2B is a cross-sectional view of the optical waveguide region 20, taken along the line IIb-IIb in FIG. 1B. FIG. 2B illustrates an optical waveguide 21c as a representative example among the optical waveguides 21a to 21e of the optical waveguide region 20. The other optical waveguides 21a, 21b, 21d, and 21e have a similar configuration with the optical waveguide 21c. The cooling structure 40 is not depicted in FIG. 2B.

The optical waveguides 21a to 21e extend along a primary surface of the semiconductor substrate 3. The optical waveguides 21a to 21e are provided for second optical waveguides in the present embodiment. The optical waveguides 21a to 21e are composed of semiconductor, for example, amorphous silicon, which is a group IV semiconductor and is different from a group III-V compound semiconductor. As illustrated in FIG. 1A, an end of the optical waveguide 21a is optically coupled with an end of the optical waveguide 110 of the semiconductor laser 11a. In a similar way, ends of the optical waveguides 21b to 21d are optically coupled respectively with ends of the optical waveguides 110 of the semiconductor lasers 11b to 11d. The other end of the optical waveguide 21a is optically coupled with an input end of a MMI coupler 22. In a similar way, the other ends of the optical waveguides 21b to 21d are optically coupled with input ends of the MMI coupler 22.

An end of the optical waveguide 21e is optically coupled with an output end of the MMI coupler 22. The other end of the optical waveguide 21e is optically coupled with an end of the optical waveguide 32 of the semiconductor optical amplifier 31. The positions of the ends of the optical waveguides 21a to 21d and the positions of the ends of the optical waveguides 110 of the semiconductor lasers 11a to 11d are adjusted respectively so as to align the centers of these propagation modes to each other and to obtain a higher coupling efficiency between the optical waveguides 21a to 21d and the optical waveguides 110 of the semiconductor lasers 11a to 11d. In this case, an optical axis of the optical waveguides 21a to 21d corresponds to an optical axis of the optical waveguides 110 of the semiconductor lasers 11a to 11d each other in the waveguiding direction. Similarly, the position of the end of the optical waveguide 21e and the position of the end of the optical waveguide 32 are adjusted so as to align the centers of these propagation modes to each other and to obtain a higher coupling efficiency between the optical waveguide 21e and the optical waveguide 32. An optical axis of the optical waveguide 21e corresponds to an optical axis of the optical waveguide 32 each other in the waveguiding direction. The thickness of the optical waveguides 21a to 21e is, for example, 0.6 μm. The width of the optical waveguides 21a to 21e in the direction perpendicular to the waveguiding direction is, for example, 1.5 μm.

As illustrated in FIGS. 1B and 2B, the optical waveguide region 20 comprises a silicon oxide (SiO₂) layer 23 and an upper cladding layer 24. The silicon oxide layer 23 is disposed between the optical waveguides 21a to 21e and the semiconductor substrate 3. The upper cladding layer 24 is disposed on the semiconductor substrate 3, and covers the optical waveguides 21a to 21e. The silicon oxide layer 23 functions as a lower cladding layer for the light propagation in the optical waveguides 21a to 21e. The upper cladding layer 24 is composed of, for example, benzocyclobutene (BCB) polymer.

The thickness of the silicon oxide layer 23 may be in the range of 1.5 μm to 4 μm. The silicon oxide layer 23 has a thickness greater than or equal to 1.5 μm. Therefore, propagating light can be effectively confined in the optical waveguide. A thickness of the silicon oxide layer 23 is not greater than 4 μm. If the thickness of the silicon oxide layer 23 is greater than 4 μm, a warpage of the semiconductor substrate 3 occurs by internal stress of the silicon oxide layer 23. Therefore, the silicon oxide layer having a thickness not greater than 4 μm can effectively suppress a warp of the semiconductor substrate 3. In an embodiment, the thickness of the silicon oxide layer 23 is 2 μm.

The semiconductor optical amplifier 31 includes a similar configuration to that of the semiconductor lasers 11a to 11d, except that the amplifier 31 does not include a diffraction grating. As illustrated in FIGS. 1A and 1B, the semiconductor optical amplifier 31 includes the optical waveguide 32, the upper cladding layer 33, and the contact layer 34. The optical waveguide 32 is disposed on the semiconductor substrate 3. The upper cladding layer 33 is disposed on the optical waveguide 32. The contact layer 34 is disposed on the upper cladding layer 33. The optical waveguide 32 is provided for a first optical waveguide in the present embodiment. The optical waveguide 32 is composed of material containing a group III-V compound semiconductor which has a longer band gap wavelength compared to the semiconductor material of semiconductor substrate 3. The optical waveguide 32 extends along a primary surface of the semiconductor substrate 3. The optical waveguide 32 is composed of a lower optical confinement layer, an active layer, and an upper optical confinement layer. The lower optical confinement layer is disposed on the semiconductor substrate 3. The active layer is disposed on the lower optical confinement layer. The upper optical confinement layer is disposed on the active layer.

In a similar configuration to the semiconductor laser 11c as illustrated in FIG. 2A, a mesa stripe structure is formed on the semiconductor substrate 3. The mesa stripe structure includes the optical waveguide 32, the upper cladding layer 33, and the contact layer 34. The mesa stripe structure is formed by etching, and has a width suitable for light propagation with a single waveguide mode. The mesa stripe structure extends toward a predetermined waveguiding direction. On both sides of the mesa stripe structure, semi-insulating regions are disposed. The semi-insulating regions are composed of the same material as that of the semi-insulating regions 102 of the semiconductor laser 11c.

An anode electrode 35 is disposed on the contact layer 34. The anode electrode 35 is composed of, for example, Ti/Pt/Au. This structure produces ohmic contact between the anode electrode 35 and the contact layer 34. The cathode electrode 103 is disposed on the back surface of the semiconductor substrate 3. The cathode electrode 103 is a common electrode to the semiconductor laser region 10. The optical waveguide 32 is supplied with electric current from the anode electrode 35 to the cathode electrode. 103. The upper surface of the light amplification region 30 other than the region of the anode electrode 35 is protected by an insulating film 5. The insulating film 5 is composed of, for example, SiO₂.

As illustrated in FIGS. 1A and 1B, an anti reflection (AR) film 37 is disposed on the end facet of the light amplification region 30 in the waveguiding direction D1. The reflectivity of the AR film 37 is, for example, 0.1%.

The semiconductor integrated optical device 1A operates as follows. When electric current is supplied to anode electrodes 117 of semiconductor lasers 11a to 11d, semiconductor lasers 11a to 11d emit light with different wavelengths from one another because of the diffraction grating 114a with different pitches from one another. The propagation modes of the laser lights have transversely ellipsoidal forms.

Thus, four output laser light components from the semiconductor lasers 11a to 11d propagate respectively in the waveguides 21a to 21d and are input to a MMI coupler 22. The MMI coupler 22 couples or multiplexes these laser light components. The MAO coupler 22 outputs the coupled light components through the optical waveguide 21e to a light amplifier region 30. On this occasion, the intensity of each of the laser light components becomes a quarter of its initial intensity.

In the light amplifier region 30, electric current is supplied to an anode electrode 35 of a semiconductor optical amplifier 31. The laser light in the active layer of an optical waveguide 32 is amplified by injecting the current. The amplified light is output through an AR film 37 to the exterior of the semiconductor integrated optical device 1A.

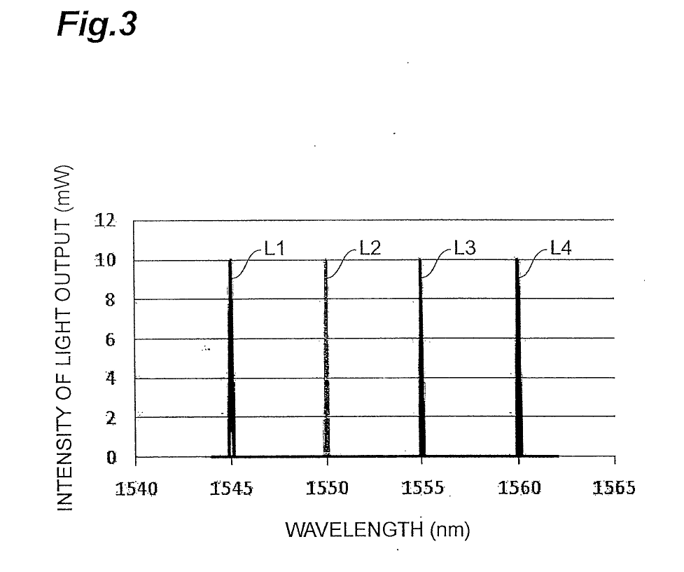

FIG. 3 illustrates a typical laser light output spectrum from the semiconductor integrated optical device 1A used as a light source that outputs four laser light components having different wavelengths simultaneously. In this case, as shown in FIG. 3, four laser light components L1 to L4 have different wavelengths from each other. The laser light components L1 to L4 are output from semiconductor lasers 11a to 11d, respectively. The laser light components L1 to L4 are contained in the laser light output.

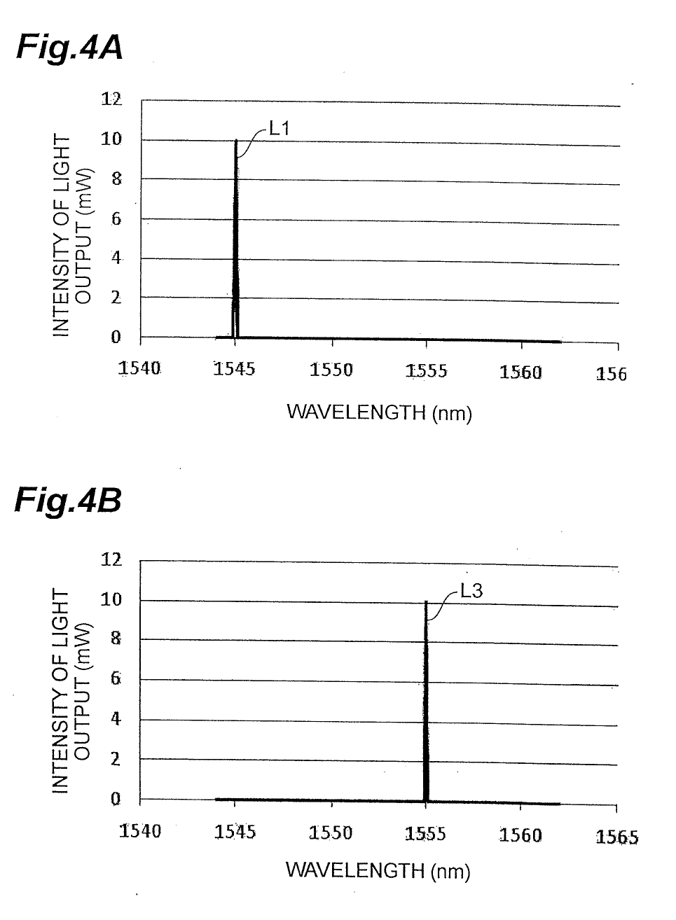

FIGS. 4A and 4B illustrate typical laser light output spectra from the semiconductor integrated optical device 1A used as a wavelength-switchable light source. FIG. 4A illustrates a spectrum in the case that the laser light L1 is contained alone in the laser output by operating only the semiconductor laser 11a. FIG. 4B illustrates a spectrum in the case that the laser light L3 is contained alone in the laser output after switching the operation to another semiconductor laser 11c.

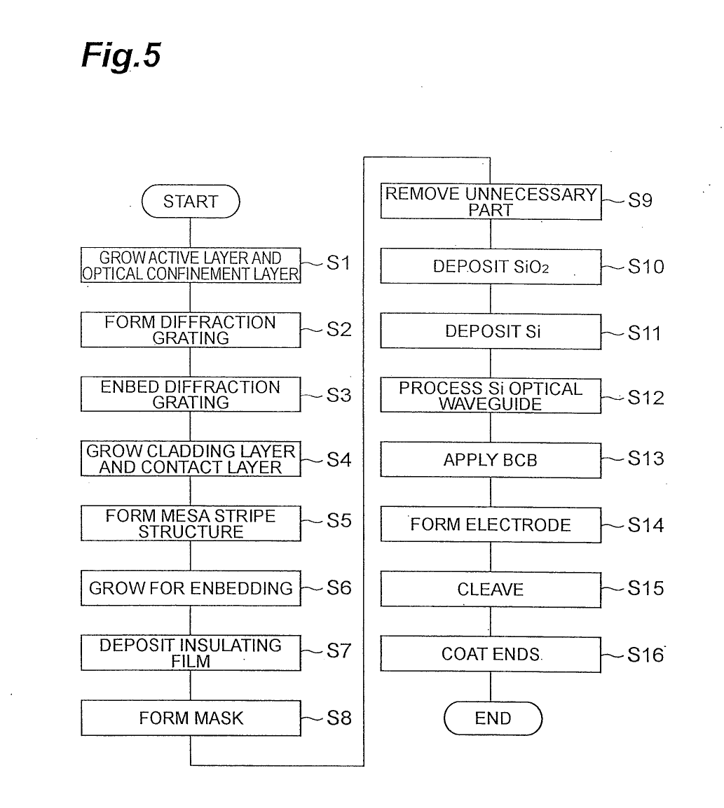

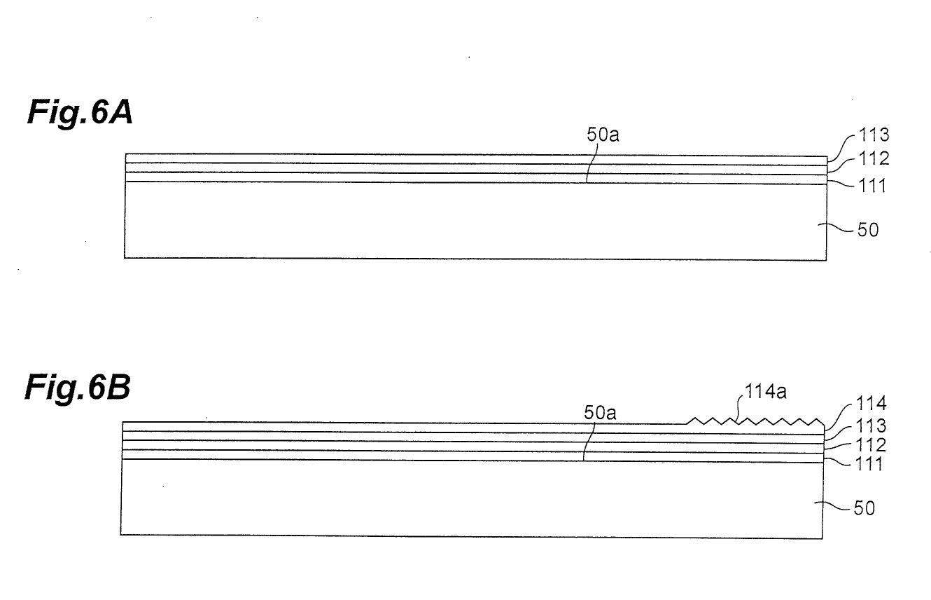

A method of making of the semiconductor integrated optical device 1A will be described below. FIG. 5 is a flow chart showing steps of the method of making the semiconductor integrated optical device 1A. FIGS. 6 to 13 illustrate manufacturing steps of the semiconductor integrated optical device 1A in sequence.

First, with reference to FIG. 6A, a wafer 50 is prepared. The wafer 50 is a semiconductor substrate composed of n-type InP. Then, on a primary surface 50a of the wafer 50, a group III-V compound semiconductor layer is grown to form optical waveguides 110 and 32. In detail, a lower optical confinement layer 111, an active layer 112, and an upper optical confinement layer 113 are epitaxially grown in sequence by metal-organic vapor phase epitaxy (MOVPE) on the primary surface 50a (step S1 in FIG. 5). The active layer 112 includes barrier layers and quantum well layers. The barrier layers and the quantum well layers are disposed alternately. The well layer is composed of an un-doped GaInAsP and the barrier layer is composed of another un-doped GaInAsP with a composition different from that of the well layers. The preferred total thickness of the barrier layers and the quantum well layers of the active layer 112 is, for example, 120 nm. The preferred band gap wavelength of the quantum well layers of the active layer 112 is 1.55 μm. The lower optical confinement layer 111 and the upper optical confinement layer 113 are composed of undoped GaInAsP. The preferred band gap wavelength of the optical confinement layers 111 and 113 is 1.2 μm and the preferred thickness of them is 80 nm.

Subsequently, a diffraction grating is formed (step S2 in FIG. 5). As shown in FIG. 6B, a diffraction grating layer 114 is epitaxially grown on the upper optical confinement layer 113 by MOVPE. The diffraction grating layer 114 is composed of p-type GaInAsP. The preferred band gap wavelength of the diffraction grating layer 114 is 1.2 μm. The preferred thickness of the diffraction grating layer 114 is, for example, 20 nm. Then, a diffraction grating 114a is formed on the surface of the diffraction grating layer 114 corresponding to the semiconductor laser region 10. This diffraction grating 114a has a periodic corrugation with a predetermined pitch. In this case, the pitch of the corrugation differs from one another in the corresponding region of each of the semiconductor lasers 11a to 11d. A coupling coefficient κ of the diffraction grating 114a is, for example, not higher than 40 cm⁻¹. The diffraction grating 114a is formed by, for example, the following method. On the surface of the diffraction grating layer 114, a patterned mask for the diffraction grating 114a is formed by electron beam exposure. Then, the diffraction grating layer 114 is processed by dry etching to form the diffraction grating 114a by using the patterned mask.

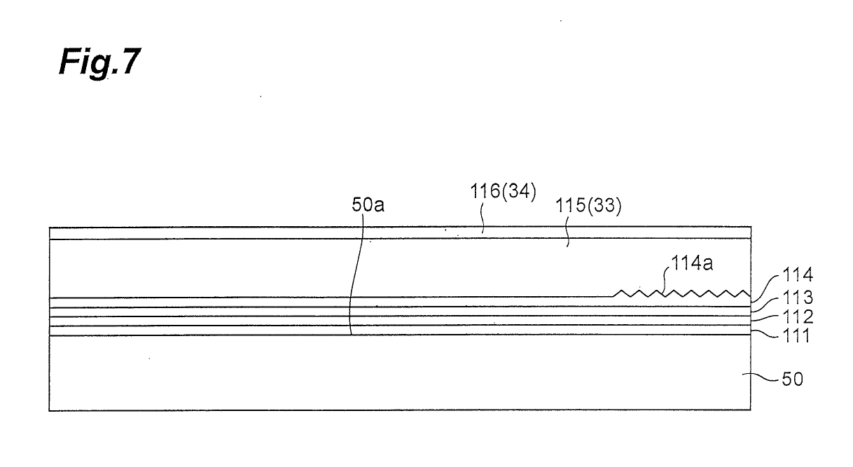

Subsequently, p-type InP is grown on the diffraction grating layer 114 by MOVPE in order to bury the diffraction grating 114a (step S3 in FIG. 5). As shown in FIG. 7, an upper cladding layer 115 (33) and a contact layer 116 (34) are epitaxially grown in sequence by MOVPE (step S4 in FIG. 5). The upper cladding layer 115 (33) is composed of p-type InP. The contact layer 116 (34) is composed of p-type GaInAs. The preferred thickness of the upper cladding layer 115 (33) is 2 μm. The preferred thickness of the contact layer 116 (34) is 200 nm.

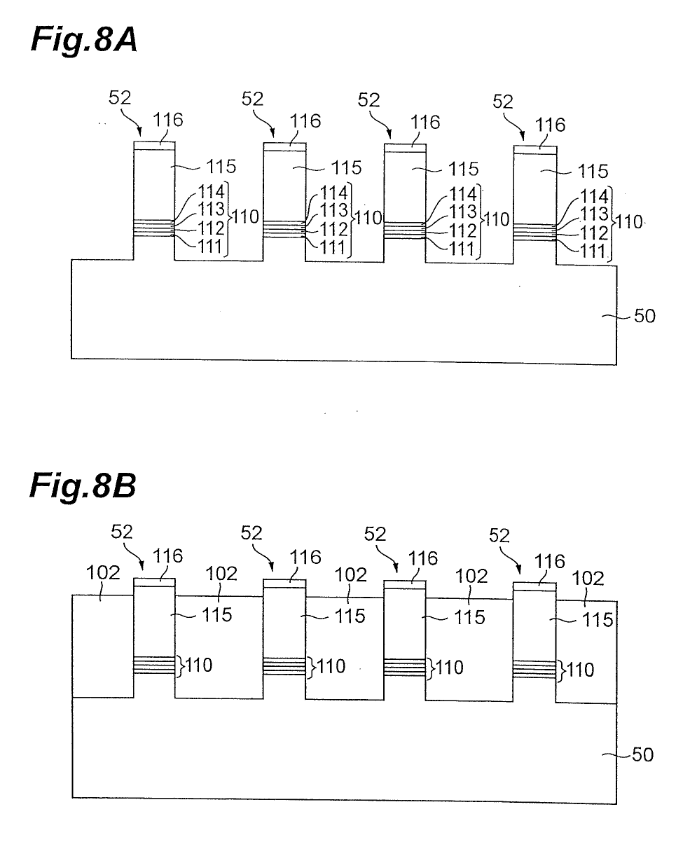

Subsequently, as shown in FIG. 8A, mesa stripe structures 52 are formed (step S5 in FIG. 5). The mesa stripe structures 52 are formed by dry-etching the layers on the wafer 50 other than the portion to be the optical waveguides 110 by exposing the wafer 50. On this occasion, a similar mesa stripe structure for the optical waveguide 32 is also formed. The height of these mesa stripe structures (i.e. etching depth) is, for example, 3.5 μm. The width of these mesa stripe structures in the direction perpendicular to the waveguiding direction is, for example, 1.8 μm. The spacings between the mesa stripe structures 52 are, for example, 100 μm. Preferably, CH₄/H₂ and O₂ are alternately used as etching gases. By this step, the optical waveguides 110 of the semiconductor lasers 11a to 11d and the optical waveguide 32 of the semiconductor optical amplifier 31 are formed.

Subsequently, as shown in FIG. 8B, high-resistivity semiconductor such as InP doped with Fe is grown on an exposed primary surface of the wafer 50 by MOVPE. Thus, semi-insulating regions 102 are formed and bury both sides of mesa stripe structures 52 (step S6 in FIG. 5).

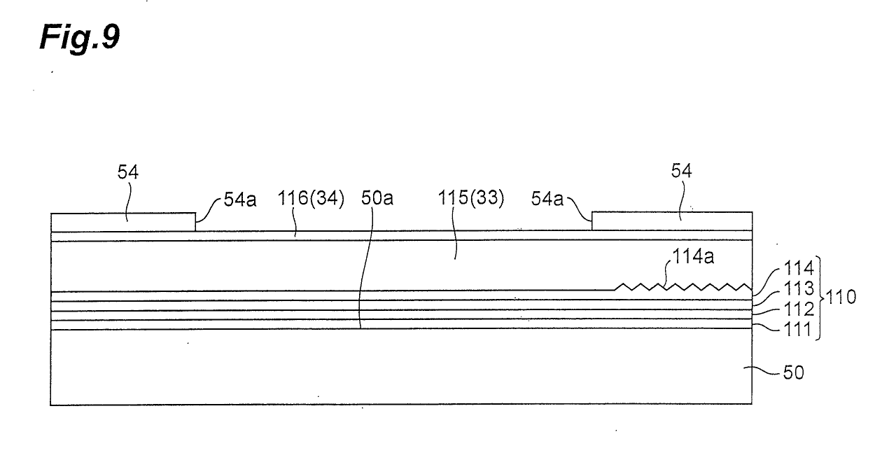

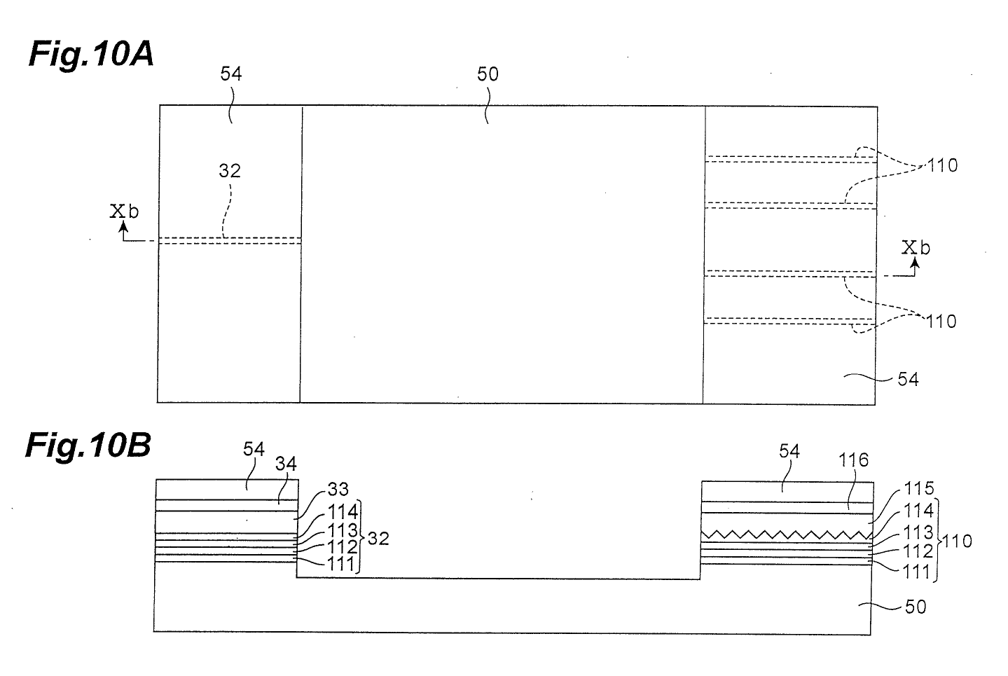

Subsequently, a part of the individual semiconductor layers deposited on a region for an optical waveguide region 20 is removed. First, an insulating film such as SiO₂ is deposited on the entire primary surface of the wafer 50 (step S7 in FIG. 5). A part of the insulating film deposited on the region for the optical waveguide region 20 is removed. Thus, as shown in FIG. 9, a mask 54 having an aperture 54a is formed (step S8 in FIG. 5). Then, the layered structure on the wafer 50 is dry-etched by using the mask 54 as an etching mask. As a result, as shown in FIGS. 10A and 10B, the part of the layered structure is removed (step S9 in FIG. 5). The preferred method of etching is, for example, reactive ion etching (RIE). The preferred etching gas is, for example, Cl₂. The preferred etching depth is, for example, 4.7 μm. After the etching, the mask 54 is removed with hydrofluoric acid.

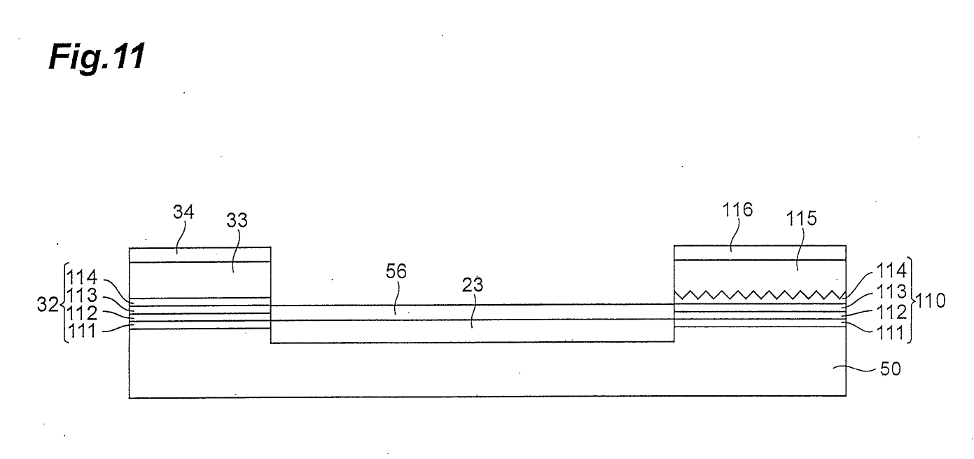

Subsequently, as shown in FIG. 11, a silicon oxide (SiO₂) layer 23 is deposited (step S10 in FIG. 5) on the region of the wafer 50 for the optical waveguide region 20. In addition, an amorphous silicon (a-Si) layer 56 is deposited (step S11 in FIG. 5) thereon. Preferably, for the deposition of the silicon oxide layer 23, SiO₂ may be deposited by, for example, inductively-coupled plasma CVD (ICP-CVD). The preferred raw material is tetraethoxysilane (TEOS). Preferably, the amorphous silicon layer 56 may be deposited by ECR sputtering. ECR sputtering enables deposition of a dense film. For example, the surface roughness Ra of the film measured by atomic force microscopy is about 5 nm. Thus, the propagation loss in the optical waveguides 21a to 21e can be reduced compared to other methods such as magnetron sputtering. The thickness of the amorphous silicon layer 56 is, for example, 0.6

As described above, preferably an ICP-CVD method is used for depositing the silicon oxide layer 23. In this case, through the adjustment of the supplied electric power to the upper electrode and the lower electrode of the ICP-CVD equipment, the internal stress of the silicon oxide layer 23 can be readily controlled. The preferred internal stress of the silicon oxide layer 23 is a compressive stress in the range of several tens of megapascals to several hundreds megapascals. The internal compressive stress of the silicon oxide layer 23 is preferably in the range of 50 MPa to 500 MPa. In cases where the internal stress is a compressive stress greater than or equal to 50 MPa, flaking or cracking of the silicon oxide layer 23 can be suppressed even if the silicon oxide layer 23 is relatively thick, for example, greater than or equal to 2 μm thick. In cases where the internal stress is a compressive stress not greater than 500 MPa, a warp of the wafer 50 can be suppressed to enhance lithographic precision in a post-process.

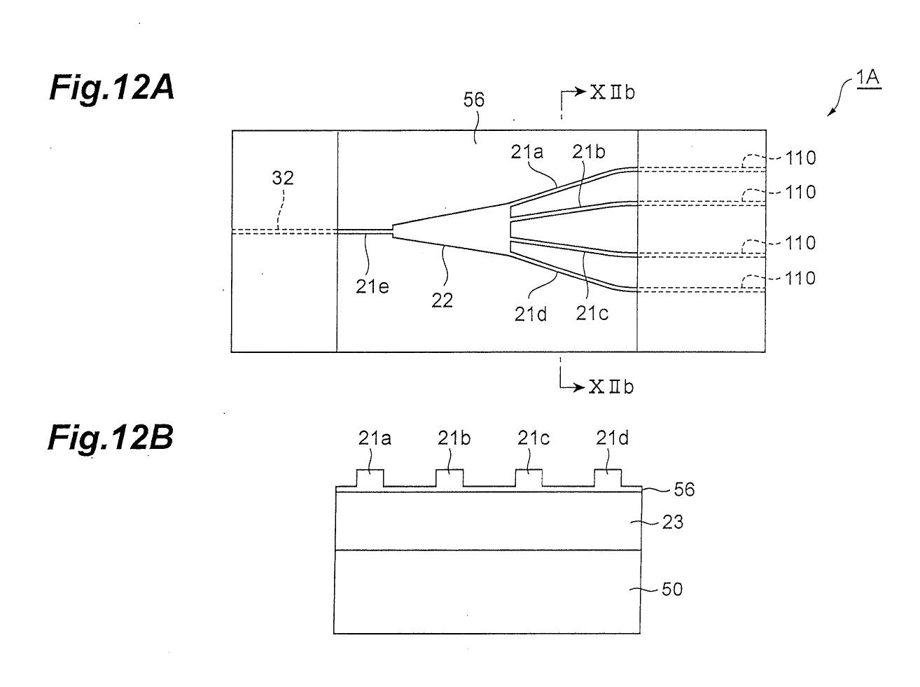

Subsequently, as shown in FIGS. 12A and 12B, the amorphous silicon layer 56 is processed to form optical waveguides 21a to 21e and an MMI coupler 22 (Step S12 in FIG. 5). In particular, a resist mask, which has the same pattern as the planar pattern of the optical waveguides 21a to 21e and the MMI coupler 22, is formed on the amorphous silicon layer 56. Then, the amorphous silicon layer 56 is dry-etched by using the resist mask as an etching mask. On this occasion, the preferred etching gas is, for example, SF₆. The preferred etching depth is, for example, 0.5 μm. Thus, a thin (0.1 μm thick) amorphous silicon layer can be left in the circumference of the optical waveguides 21a to 21e.

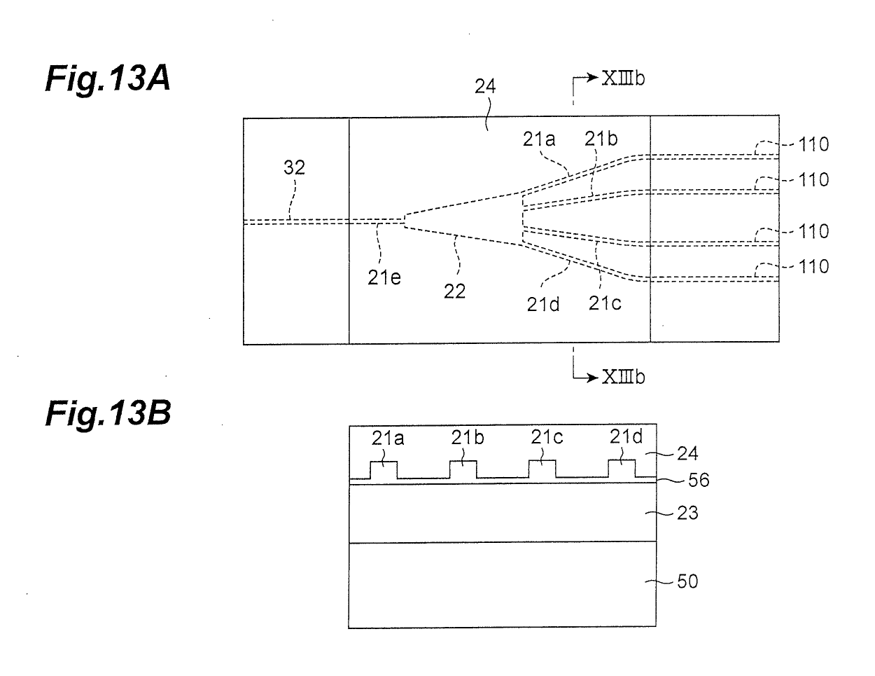

Subsequently, as shown in FIGS. 13A and 13B, BCB resin is disposed on the silicon oxide layer 23 in order to cover the optical waveguides 21a to 21e and the MMI coupler 22. Then, a portion of the BCB resin disposed on the region for the optical waveguide region 20 is selectively cured. An upper cladding layer 24 is thereby formed (step S13 in FIG. 5).

Subsequently, the insulating film (SiO₂) deposited on the semiconductor laser region 10 and the light amplification region 30 is dry-etched. On this occasion, hydrofluoric acid or CF₄ gas is used. The insulating film is thereby thinned to foam insulating films 4 and 5. On this occasion, preferably the etching is terminated when the thickness of the insulating film is reduced to a range of 0.3 μm to 2 μm. Then, the portions of the insulating films 4 and 5 located above the optical waveguides 110 and 32 are completely removed to form apertures on the contact layers 116 and 34. By a lift-off process, anode electrodes 117 are fanned on the contact layer 116, and another anode 35 is formed on the contact layer 34. A cathode electrode 103 is evaporated on the back surface of the wafer 50 (step S14 in FIG. 5).

Finally, the wafer 50 is cleaved into a bar-shape (step S15 in FIG. 5). A cleavage surface of the bar-shaped product is coated by a HR film 105. Another cleavage surface of the bar-shaped product is coated by an AR film 37 (step S16 in FIG. 5). Then, this bar-shaped product is divided into a plurality of chips. Each chip is mounted by die bonding on a cooling structure 40. The semiconductor integrated optical device 1A of the present embodiment is completed in such a manner.

The semiconductor integrated optical device 1A of the present embodiment and the method of making the same have the following advantages. As described above, the semiconductor integrated optical device 1A comprises the semiconductor laser region 10, the light waveguide region 20, and the light amplification region 30 disposed on a single semiconductor substrate 3. The optical waveguides 110 of the semiconductor laser region 10 and the optical waveguide 32 of the light amplification region 30 comprise a group III-V compound semiconductor. Accordingly, as described with reference to FIGS. 6A and 6B, the waveguides 110 and 32 can be epitaxially grown on the wafer 50 (i.e. semiconductor substrate 3). On the other hand, a silicon oxide layer 23 is disposed between the optical waveguides 21a to 21e of the optical waveguide region 20 and the semiconductor substrate 3. As described above, the silicon oxide layer 23 can be formed by, for example, ICP-CVD. The overlying optical waveguides 21a to 21e can be foamed preferably by depositing a semiconductor such as silicon which is a group IV semiconductor and is different from the group III-V compound semiconductor.

Thus, the optical waveguides 110 can be aligned precisely to the optical waveguides 21a to 21d. The optical waveguide 32 can be aligned precisely to the optical waveguide 21e. The vertical positions of these optical waveguides can be adjusted accurately through control of thickness of the silicon oxide layer 23 and semiconductor layers. The thickness of each layer is controlled accurately by determination of the time of deposition. The horizontal positions of these optical waveguides can be adjusted accurately through photolithographic formation of the optical waveguides 110 and 32 and the optical waveguides 21a to 21e. Thus, the semiconductor integrated optical device 1A made by the method as described above can exhibit an enhanced optical coupling efficiency between the optical waveguide region 20 and the semiconductor optical device region, which is composed of the semiconductor laser region 10 and the light amplification region 30.

In the present embodiment of the semiconductor integrated optical device 1A and the method of making the same, as shown in FIGS. 6 to 13, the semiconductor optical device region, which is composed of the semiconductor laser region 10 and the light amplification region 30, and the optical waveguide region 20 can be formed by growth or deposition of preferred materials on the substrate 3 (i.e. wafer 50). Since the alignment between the regions can be readily achieved, the yield rate of the resulting product can be improved.

In the present embodiment, core regions of the optical waveguides 110 are aligned respectively to core regions of the optical waveguides 21a to 21d, and a core region of the optical waveguide 32 is aligned to a core region of the optical waveguide 21e. Thus, the vertical and horizontal positions of the optical waveguides 110 and 32 and the optical waveguides 21a to 21e are adjusted.

The optical waveguides 21a to 21e composed of silicon have the following effects. Compared to the optical waveguides composed of group III-V compound semiconductor, the capability of the optical confinement can be enhanced due to an increased difference in refractive index between the optical waveguides 21a to 21e and the circumference. Thus, the spacings between the optical waveguides 21a to 21e can be narrowed (e.g. 0.1 μm to 0.5 μm). In addition, the bending radius of the optical waveguide 21a to 21e can be shortened. As a result, the semiconductor integrated optical device 1A can become smaller.

The semiconductor laser region 10 comprises a plurality of semiconductor lasers 11a to 11d. Between the semiconductor lasers 11a to 11d, the laser wavelength may differ from one another. Such a configuration can readily produce a transmission device for a wavelength division multiplexing (WDM) system.

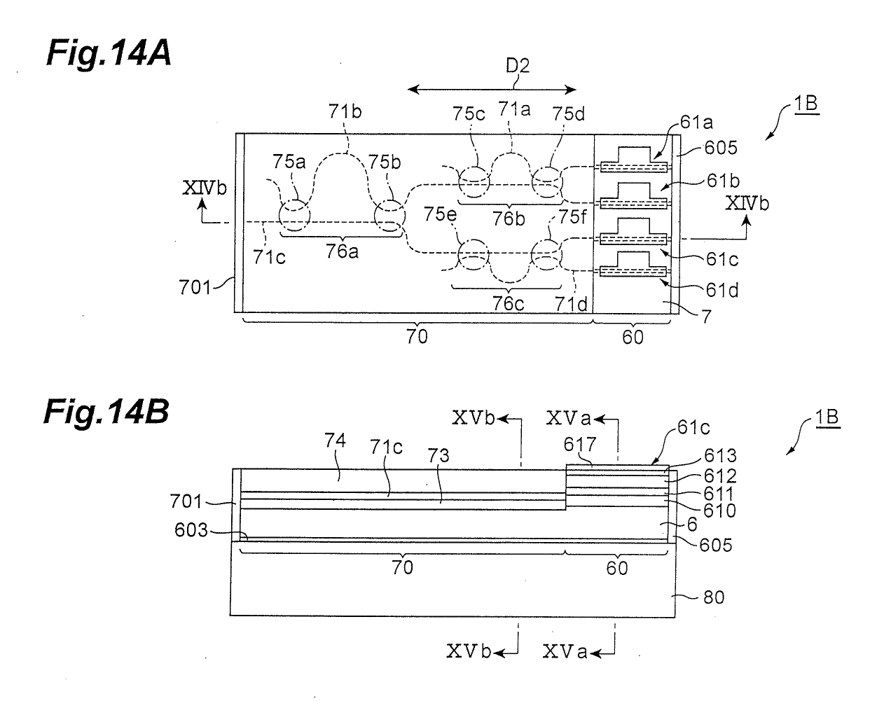

FIG. 14A is a plan view of a semiconductor integrated optical device in a second embodiment of the present invention. FIG. 14B is a cross-sectional view taken along the line XIVb-XIVb in FIG. 14A. As shown in FIGS. 14A and 14B, the semiconductor integrated optical device 1B comprises a photodiode region 60 and an optical waveguide region 70. The photodiode region 60 has photodiode structures 61a to 61d. The optical waveguide region 70 has optical waveguides 71a to 71d. The photodiode region 60 is provided for a semiconductor optical device region of the present embodiment. As shown in FIG. 14B, the photodiode region 60 and the optical waveguide region 70 are formed on a semiconductor substrate 6. The photodiode region 60 and the optical waveguide region 70 are arranged in a predetermined direction D2. The semiconductor substrate 6 can be a group III-V compound semiconductor substrate in the present embodiment. The semiconductor substrate 6 is composed of first conductive type semiconductor such as n-type InP. The semiconductor substrate 6 functions as a lower cladding layer in the photodiode layer 60.

The semiconductor integrated optical device 1B A is disposed on a cooling structure 80. The cooling structure 80 includes a similar configuration with the cooling structure 40 in order to keep the semiconductor substrate 6 and the layered structure on the primary surface of the substrate 6 at constant temperature.

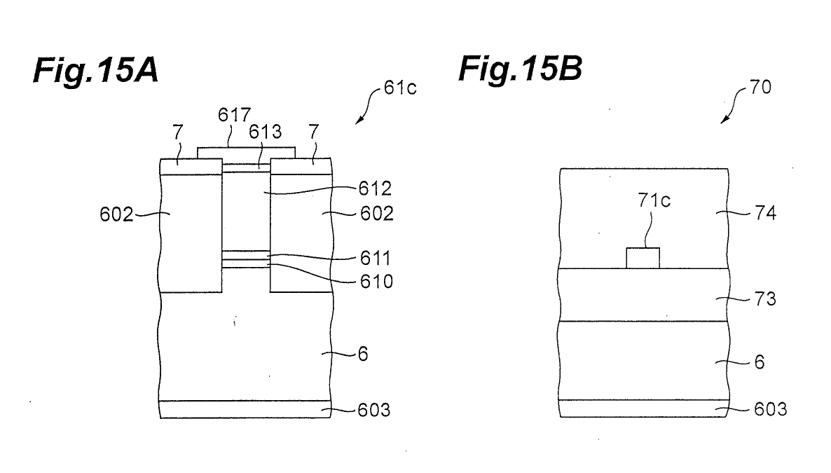

With reference to FIGS. 14A, 14B and 15A, the configuration of the photodiode structures 61a to 61d included in the photodiode region 60 will be explained. FIG. 15A is a cross-sectional view of the photodiode region 60, taken along the line XVa-XVa in FIG. 14B. FIG. 15A illustrates a photodiode structure 61c as a representative example among the photodiode structures 61a to 61d of the photodiode region 60. The other photodiode structures 61a, 61b, and 61d have a similar structure with the photodiode structures 61c. The cooling structure 80 is not depicted in FIG. 15A.

The photodiode structure 61c includes a first optical waveguide 610, a light-absorbing layer 611, an upper cladding layer 612, and a contact layer 613. The optical waveguide 610 is disposed on the semiconductor substrate 6. The light-absorbing layer 611 is disposed on the optical waveguide 610. The upper cladding layer 612 is disposed on the light-absorbing layer 611. The contact layer 613 is disposed on the upper cladding layer 612. The optical waveguide 610 is composed of material containing group III-V compound semiconductor which has a longer band gap wavelength or a smaller band gap energy compared with the semiconductor material of the semiconductor substrate 6. The optical waveguide 610 extends along a primary surface of the semiconductor substrate 6 toward the waveguiding direction.

The optical waveguide 610 is composed of, for example, undoped GaInAsP. The light-absorbing layer 611 is composed of, for example, undoped GaInAs. The composition of the light-absorbing layer 611 is determined so as to absorb light having, for example, the 1.3 μm wavelength band or the 1.55 μm wavelength band. The upper cladding layer 612 and the contact layer 613 are composed of second conductive type group III-V compound semiconductor. For example, the upper cladding layer 612 is composed of p-type InP. The contact layer 613 is composed of p-type GaInAs.

A mesa stripe structure is formed on the semiconductor substrate 6. The mesa stripe structure includes the optical waveguide 610, the light-absorbing layer 611, the upper cladding layer 612, and the contact layer 613. The mesa stripe structure extends toward a predetermined waveguiding direction. The mesa stripe structure is formed by etching, and has a width suitable for light propagation with a single waveguide mode. The width of the mesa stripe structure in the direction intersecting the waveguiding direction is, for example, 1.8 μm. On both sides of the mesa stripe structure, semi-insulating regions 602 are disposed. The semi-insulating regions 602 are composed of semi-insulating or high-resistivity semiconductor such as InP doped with Fe. The semi-insulating regions 602 are disposed on the surface of the semiconductor substrate 6 to bury the both sides of the mesa stripe structure.

An anode electrode 617 is disposed on the contact layer 613. The anode electrode 617 is composed of, for example, Ti/Pt/Au. This structure produces ohmic contact between the anode electrode 617 and the contact layer 613. A cathode electrode 603 is disposed on the back surface of the semiconductor substrate 6. The cathode electrode 603 is composed of, for example, AuGe. This structure produces ohmic contact between the cathode electrode 603 and the semiconductor substrate 6. The light-absorbing layer 611 generates photoelectric current. The photoelectric current flows between the anode electrode 617 and the cathode electrode 603. The upper surface of the photodiode region 60 other than the region of the anode electrode 617 is protected by an insulating film 7. The insulating film 7 is composed of, for example, SiO₂.

With reference to FIGS. 14A, 14B and 15B, the configuration of an optical waveguide region 70 will be explained below. FIG. 15B is a cross-sectional view of the optical waveguide region 70, taken along the line XVb-XVb in FIG. 14B. FIG. 15B illustrates an optical waveguide 71c as a representative example among the optical waveguides 71a to 71d of the optical waveguide region 70. The other optical waveguides 71a, 71b, and 71d have a similar configuration with the optical waveguide 71c. The cooling structure 80 is not depicted in FIG. 15B.

The optical waveguides 71a to 71d extend along a primary surface of the semiconductor substrate 6. The optical waveguides 71a to 71d are provided for second optical waveguides in the present embodiment. The optical waveguides 71a to 71d are composed of semiconductor such as amorphous silicon which is a group IV semiconductor and is different from a group III-V compound semiconductor. As illustrated in FIG. 14A, an end of the optical waveguide 71a is optically coupled with an end of the optical waveguide 610 of the photodiode structure 61a. Similarly, ends of the optical waveguides 71b to 71d are optically coupled respectively with ends of the optical waveguides 610 of the photodiode structures 61b to 61d. The other end of the optical waveguide 71c reaches an end facet of the optical waveguide region 70. The positions of the ends of the optical waveguides 71a to 71d and the positions of the ends of the optical waveguides 610 of the photodiode structures 61a to 61d are adjusted respectively so as to align the core regions of these optical waveguides to each other for obtaining a higher optical coupling efficiency. In this case, an optical axis of the optical waveguides 71a to 71d corresponds to an optical axis of the optical waveguides 610 of the photodiode structures 61a to 61d each other in the waveguiding direction. The thickness of the optical waveguides 71a to 71d is, for example, 0.8 μm. The width of the optical waveguides 71a to 71d in the direction perpendicular to the waveguiding direction is, for example, 0.8 μm.

The optical waveguide region 70 comprises a wavelength multi/demultiplexer using a Mach-Zehnder interferometer. The optical waveguides 71a to 71d include the following configuration so as to compose the optical multi/demultiplexer. In other words, the optical waveguide 71c as an input optical waveguide and the optical waveguide 71b is coupled with a pair of directional couplers 75a and 75b. The arm length or optical length of the optical waveguides 71b and 71c in the connection portion is different from each other. Consequently, the optical waveguides 71b and 71c constitute a Mach-Zehnder interferometer 76a. Similarly, the optical waveguides 71a and 71b are coupled with a pair of directional couplers 75c and 75d. The arm length or optical length of the optical waveguides 71a and 71b in the connection portion is different from each other. Consequently, the optical waveguides 71a and 71b constitute a Mach-Zehnder interferometer 76b. The optical waveguides 71c and 71d are coupled with a pair of directional couplers 75e and 75f. The arm length or optical length of the optical waveguides 71c and 71d in the coupled portion is different from each other. Consequently, the optical waveguides 71c and 71d constitute a Mach-Zehnder interferometer 76c.

Assuming that the arm length of the optical waveguide 71b in the Mach-Zehnder interferometer 76a is A1, and the arm length of the optical waveguide 71c in the Mach-Zehnder interferometer 76a is A2, the difference (A1−A2) between A1 and A2 is, for example, 68.272 μm. Assuming that the arm length of the optical waveguide 71a in the Mach-Zehnder interferometer 76b is A3, and the arm length of the optical waveguide 71b in the Mach-Zehnder interferometer 76b is A4, the difference (A3−A4) between A3 and A4 is, for example, 34.136 μm. Assuming that the arm length of the optical waveguide 71c in the Mach-Zehnder interferometer 76c is A5, and the arm length of the optical waveguide 71d in the Mach-Zehnder interferometer 76c is A6, the difference (A5−A6) between A5 and A6 is, for example, −34.022 μm. Since the optical waveguides 71a to 71d are composed of silicon, the effective refractive index of the waveguides is 3.4 for the light having a wavelength of 1.55 μm.

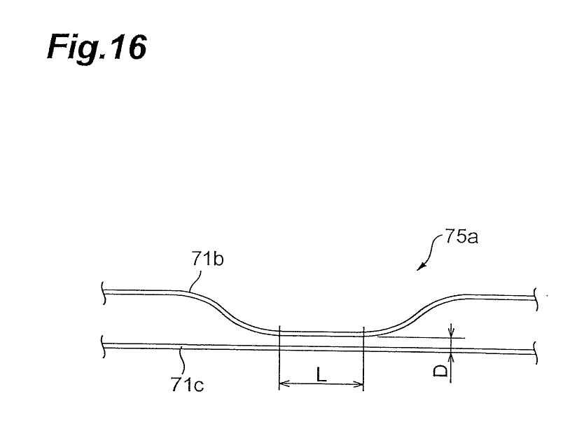

A typical configuration of directional couplers 75a to 75f will be described below. FIG. 16 illustrates a plan view of the directional coupler 75a. As shown in FIG. 16, the directional coupler 75a optically partially couples the two optical waveguides 71b and 71c with a short distance therebetween. The length L of the coupled portion of the optical waveguides 71b and 71c is, for example, 100 μm. The distance “D” between the optical waveguides 71b and 71c is, for example, 0.3 μm. In this case, the coupling fraction of the directional coupler 75a is 0.5. Other directional couplers 75b to 75f have a similar configuration with the directional coupler 75a shown in FIG. 16.

As shown in FIGS. 14A, 14B and 15B, the optical waveguide region 70 comprises a silicon oxide layer 73 and the upper cladding layer 74. The silicon oxide layer 73 is disposed between the optical waveguides 71a to 71d and the semiconductor substrate 6. The upper cladding layer 74 is disposed on the semiconductor substrate 6, and covers the optical waveguides 71a to 71d. The silicon oxide layer 73 functions as a lower cladding for the light propagation in the optical waveguides 71a to 71d. The upper cladding layer 74 is composed of SiO₂, like the silicon oxide layer 73.

The thickness of the silicon oxide layer 73 may be in the range of 1.5 μm to 4 μm, for the same reason as the silicon oxide layer 23 in the first embodiment. In other words, the silicon oxide layer 73 has a thickness greater than or equal to 1.5 μm. Therefore, propagating light can be effectively confined in the optical waveguide. A thickness of the silicon oxide layer 73 is not greater than 4 μm. If the thickness of the silicon oxide layer 73 is greater than 4 μm, a warpage of the semiconductor substrate 3 occurs by internal stress of the silicon oxide layer 73. In an embodiment, the thickness of the silicon oxide layer 73 is 2 μm.

As shown in FIGS. 14A and 14B, an AR film 605 is disposed on an end facet of the photodiode region 60 in the predetermined direction D2. An AR film 701 is disposed on an end facet of the optical waveguide region 70 in the predetermined direction D2. The reflectivity of the AR films 605 and 701 is, for example, 0.1%.

A semiconductor integrated optical device 1B operates as follows. For example, an optical signal including four wavelength components is input to the optical waveguide 71c of a semiconductor integrated optical device 1B through the AR film 701. Two wavelength components λ1 and λ2 among the four wavelength components λ1 to λ4 selectively propagate into the optical waveguide 71b by means of the Mach-Zehnder interferometer 76a. A wavelength component λ1 selectively propagates into the optical waveguide 71a optically coupling to the photodiode structures 61a by means of the Mach-Zehnder interferometer 76b. On the other hand, a wavelength component λ2 selectively propagates into the optical waveguide 71b optically coupling to the photodiode structures 61b by means of the Mach-Zehnder interferometer 76b. The remaining wavelength components λ3 and λ4 selectively propagate into the optical waveguide 71c by means of the Mach-Zehnder interferometer 76a. A wavelength component λ3 selectively propagates into the optical waveguide 71c optically coupling to the photodiode structures 61c by means of the Mach-Zehnder interferometer 76c. On the other hand, a wavelength component λ4 selectively propagates into the optical waveguide 71d optically coupling to the photodiode structures 61d by means of the Mach-Zehnder interferometer 76c. Thus, the four wavelength components λ1 to λ4 included in an optical signal are demultiplexed and propagate into the respective optical waveguides 71a to 71d. The wavelength components λ1 to λ4 propagate into the respective optical waveguides 610 of the photodiode structures 61a to 61d. The propagation modes of the wavelength components λ1 to λ4 have substantially circular forms.

The wavelength components λ1 to λ4 reach the optical waveguides 610 of the photodiode structures 61a to 61d respectively, and propagate in the optical waveguides 610 while keeping the circular-shaped propagation mode. Then, the wavelength components λ1 to λ4 are absorbed in a light-absorbing layer 611 and are converted to photoelectric currents. These photoelectric currents are output to the external electric circuit through the anode electrode 617 and the cathode electrode 603.

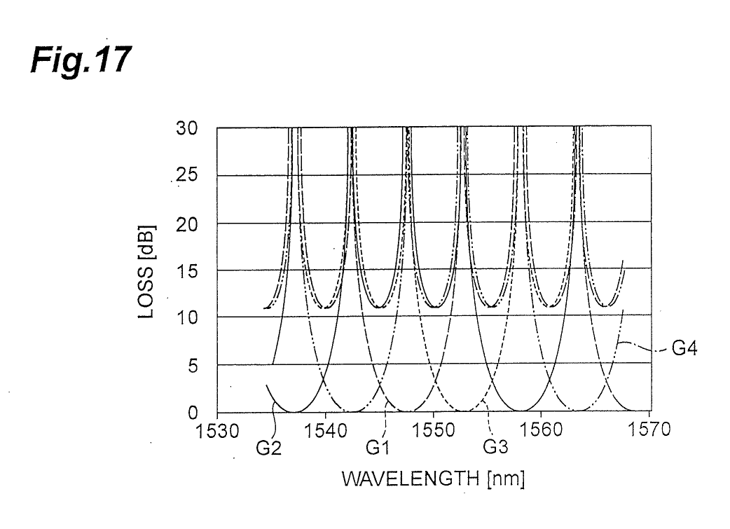

FIG. 17 is a graph showing the relationship between the optical loss of an optical multi/demultiplexer composed of Mach-Zehnder interferometers 76a to 76c and wavelength. Graph G1 in FIG. 17 shows the optical loss of the light reaching the photodiode structure 61a via the optical waveguide 71a. Graphs G2 to G4 in FIG. 17 show the optical losses of the light reaching the photodiode structures 61b to 61d from the optical waveguides 71b to 71d, respectively. As shown in FIG. 17, the wavelength exhibiting low optical loss differs from one another among the graphs G1 to G4. Therefore the different wavelength components included in an optical signal can be preferably separated for the photodiode structures 61a to 61d.

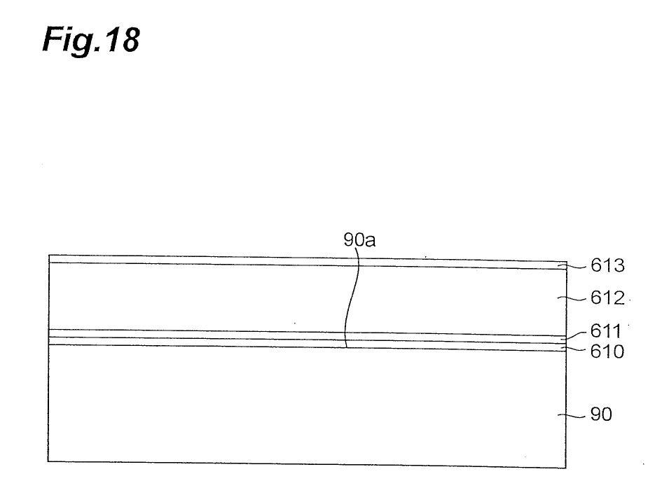

A method of making the semiconductor integrated optical device 1B will be described below. FIGS. 18 to 23B illustrate manufacturing steps of the semiconductor integrated optical device 1B in sequence.

First, with reference to FIG. 18, a wafer 90 is prepared as a substrate composed of n-type InP. Then, a semiconductor layer 610, a light-absorbing layer 611, an upper cladding layer 612, and a contact layer 613 are epitaxially grown in sequence on a primary surface 90a of the wafer 90 by MOVPE. The semiconductor layer 610 is composed of undoped GaInAsP. The light-absorbing layer 611 is composed of p-type GaInAs. The upper cladding layer 612 is composed of p-type InP. The contact layer 613 is composed of p-type GaInAs. The preferred thickness of the semiconductor layer 610 is 200 nm. The preferred thickness of the light-absorbing layer 611 is 100 nm. The preferred thickness of the upper cladding layer 612 is 2 μm. The preferred thickness of the contact layer 613 is 200 nm. The preferred band gap wavelength of the light-absorbing layer 611 is 1.3 μm.

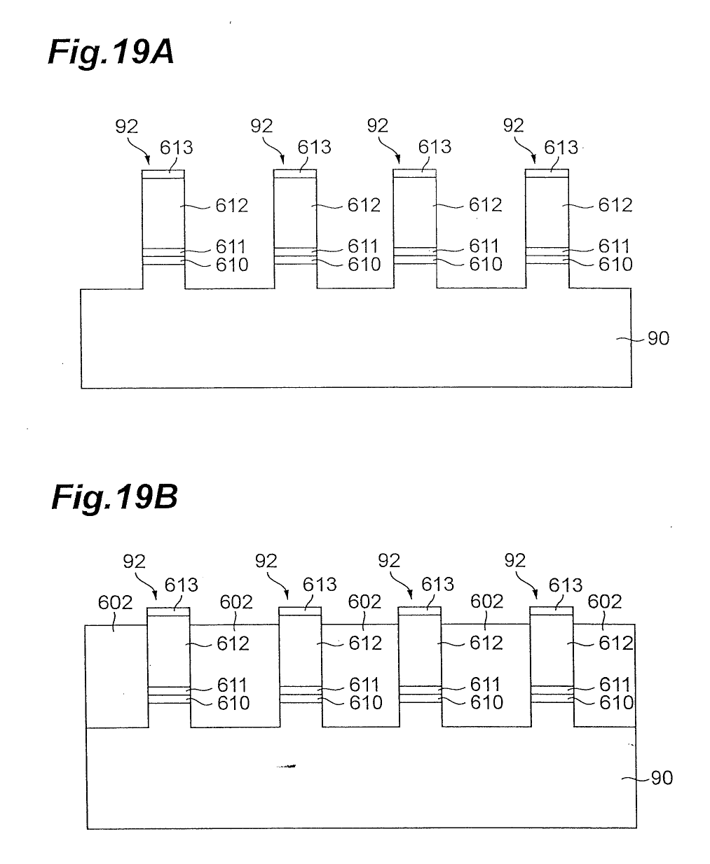

Subsequently, the layered structure on the wafer 90 other than the portion used to be the optical waveguides 610 is dry-etched by exposing the wafer 90. As shown in FIG. 19A, mesa stripe structures 92 are thereby formed. The height of these mesa stripe structures 92 (i.e. etching depth) is, for example, 3.5 μm. The width of these mesa stripe structures 92 in the direction perpendicular to the waveguiding direction is, for example, 1.8 μm. Preferably, Ca₄/H₂ and O₂ are alternately used as etching gases. By this step, the optical waveguides 610 of the photodiode structures 61a to 61d are formed.

Subsequently, as shown in FIG. 19B, a high-resistivity semiconductor such as InP doped with Fe is grown on an exposed primary surface of a wafer 90 by MOVPE. Semi-insulating regions 602 are thereby formed and bury both sides of mesa stripe structures 92.

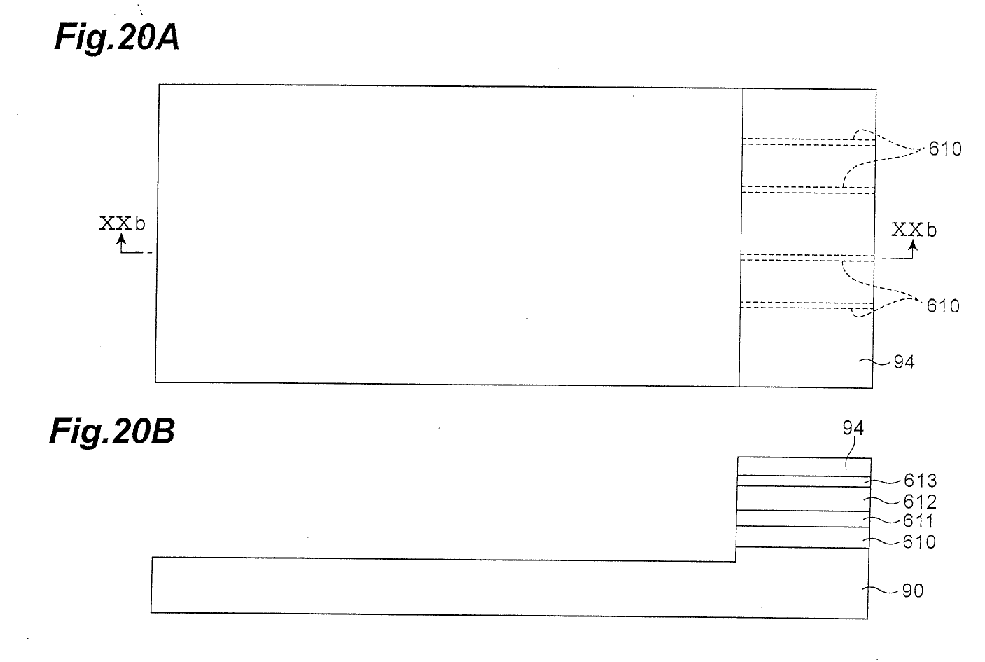

Subsequently, a part of the individual semiconductor layers deposited on a region for an optical waveguide region 70 is removed. First, an insulating film such as SiO₂ is deposited on the entire primary surface of the wafer 90. A part of the insulating film disposed on the region for the optical waveguide region 70 is removed. As shown in FIGS. 20A and 20B, a mask 94 covering only a region for the photodiode region 60 is thereby formed. Then, the layered structure on the wafer 90 is dry-etched by using the mask 94 as an etching mask. As a result, the part of the layered structure is removed. On this occasion, the method and conditions of etching are the same as described for the step S9 in the first embodiment.

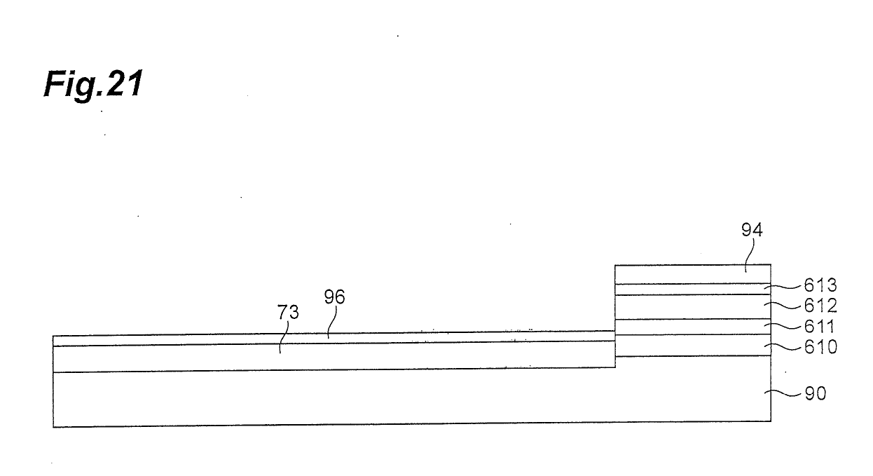

Subsequently, as shown in FIG. 21, a silicon oxide layer 73 is deposited on the region of the wafer 90 for the optical waveguide region 70. Furthermore, an amorphous silicon layer 96 is deposited thereon. The method of forming the silicon oxide layer 73 and the amorphous silicon layer 96 is the same as described for the steps S10 and S11 in the first embodiment, except that the thickness of the amorphous silicon layer 96 is, for example, 0.8 μm in the present embodiment.

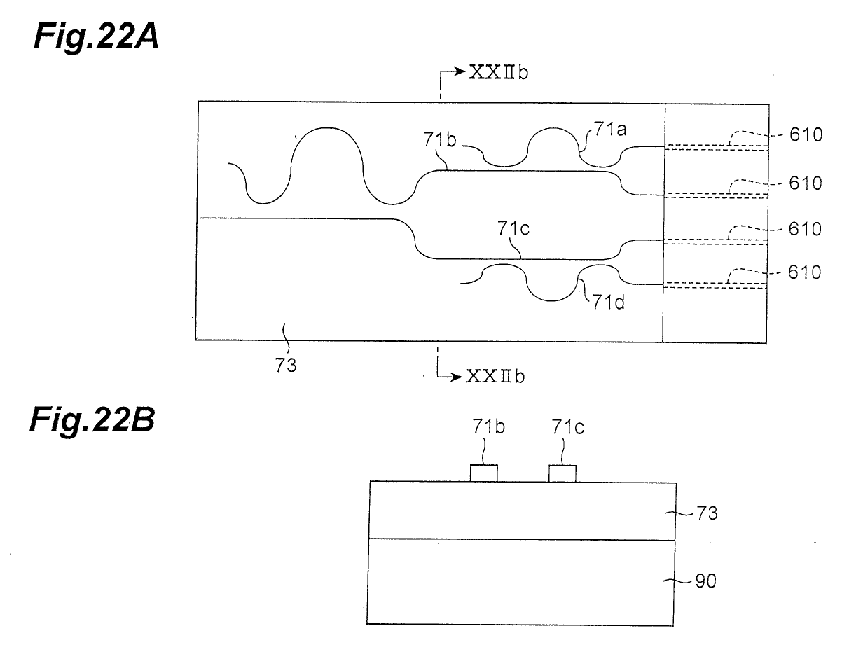

Subsequently, as shown in FIGS. 22A and 22B, the amorphous silicon layer 96 is processed to form optical waveguides 71a to 71d. In detail, a resist mask is formed on the amorphous silicon layer 96. The resist mask has the same pattern as the planar pattern of the optical waveguides 71a to 71d. Then, the amorphous silicon layer 96 is dry-etched by using the resist mask as an etching mask. On this occasion, the preferred etching gas is, for example, SF₆. The preferred etching depth is, for example, equal to the thickness of the amorphous silicon layer 96, 0.8 μm so that no amorphous silicon layer is left in the circumference of the optical waveguides 71a to 71d.

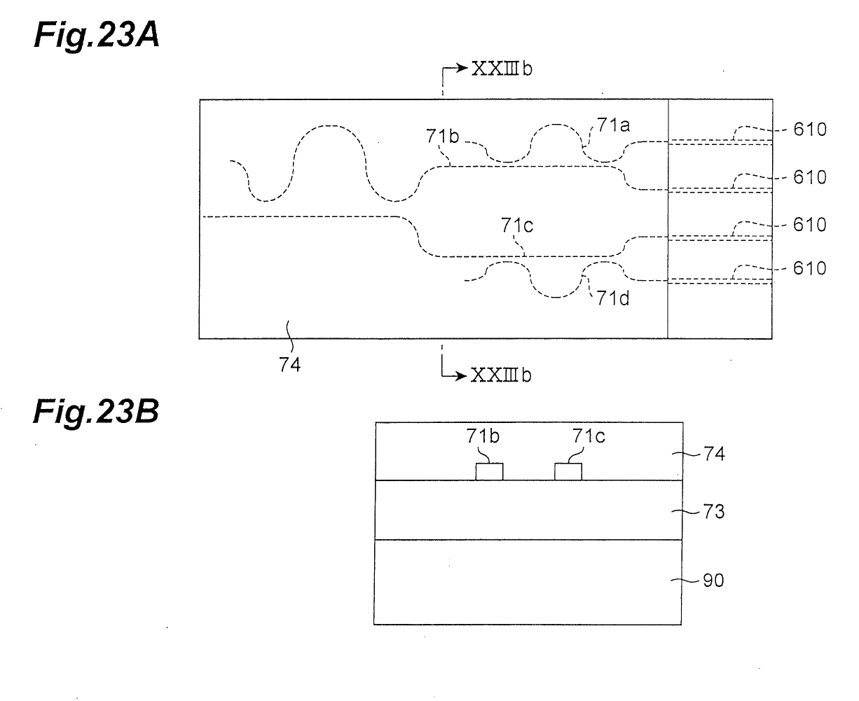

Subsequently, as shown in FIGS. 23A and 23B, an insulating film (SiO₂) is deposited on the silicon oxide layer 73 to form a cladding layer 74. The upper cladding layer 74 covers the optical waveguides 71a to 71d.

Subsequently, the insulating film deposited on the photodiode region 60 is dry-etched. On this occasion, hydrofluoric acid or CF₄ gas is used. The insulating film is thereby thinned to four an insulating film 7. On this occasion, preferably the etching is terminated when the thickness of the SiO₂ film is reduced to a range of 0.3 μm to 2 μm. Then, the portions of the insulating film 7 located above the optical waveguides 610 are completely removed to form apertures on the contact layer 613. By a lift-off process, anode electrodes 617 are formed on the contact layer 613. A cathode electrode 603 is evaporated on the back surface of the wafer 90.

Finally, the wafer 90 is cleaved into a bar-shape. A cleavage surface of the bar-shaped product is coated by an AR film 605. Another cleavage surface of the bar-shaped product is coated by an AR film 701. Then, this bar-shaped product is divided into a plurality of chips. Each chip is mounted by die bonding on a cooling structure 80. The semiconductor integrated optical device 1B of the present embodiment is completed in such a manner.

In the present embodiment of the semiconductor integrated optical device 1B and the method of making the same, the same advantages as described in the first embodiment can be provided. In other words, since the optical waveguides 610 can be aligned precisely to the optical waveguides 71a to 71d, a coupling efficiency between the photodiode region 60 (semiconductor optical device region) and the optical waveguide region 70 can be enhanced. As shown in FIGS. 18 to 23B, the photodiode region 60 (semiconductor optical device region) and the optical waveguide region 70 can be formed by growth or deposition of preferred materials on the substrate 6 (i.e. wafer 90). Since the alignment between the regions can be readily achieved, the yield rate of the resulting semiconductor integrated optical device can be improved.

The photodiode region 60 may comprises a plurality of photodiode structures 61a to 61d. The optical waveguide region 70 may comprises a multi/demultiplexer. Such a configuration can readily produces an apparatus for monitoring wavelength and power of optical signals propagated through a transmission path in a wavelength division multiplexing system.

The semiconductor integrated optical device and the method of making the same of the present invention are not limited to the two embodiments as described above; various changes and modifications may be made. For example, in the embodiments the upper cladding layer is disposed on the silicon oxide layer in order to cover the second optical waveguide. Alternatively, no upper cladding layer may be disposed on the silicon oxide layer in order to expose the second optical waveguide. Such a configuration can readily produce the advantageous effects of the present invention.

In the first embodiment, the semiconductor laser region 10 has a plurality of semiconductor lasers 11a to 11d. Alternatively, the semiconductor optical device region may have a single semiconductor laser structure. In the second embodiment, the photodiode region 60 has a plurality of photodiode structures 61a to 61d. Alternatively, the semiconductor optical device region may have a single photodiode structure. Alternatively, the semiconductor optical device region of the present invention may include various semiconductor optical device structures other than the semiconductor laser structure or photodiode structure.

In the embodiments, InP compound is explained as an example of group III-V compound semiconductors. Alternatively, group III-V compound semiconductor such as GaAs compound can produce the advantages of the present invention.

From the invention thus described, it will be obvious that the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A semiconductor integrated optical device, comprising:
a group Ill-V compound semiconductor substrate;
a semiconductor optical device region provided on the group III-V compound semiconductor substrate, the semiconductor optical device region having a first optical waveguide made of group III-V compound semiconductor; and
an optical waveguide region provided on the group III-V compound semiconductor substrate and extending along the semiconductor optical device region, the optical waveguide region having a second optical waveguide optically coupled with the first optical waveguide, the second optical waveguide extending along a primary surface of the group III-V compound semiconductor substrate,
wherein the optical waveguide region further includes a silicon oxide layer for a lower cladding layer, the silicon oxide layer being provided between the group III-V compound semiconductor substrate and the second optical waveguide, and
wherein the second optical waveguide is made of semiconductor which is different from the group III-V compound semiconductor.

2. The semiconductor integrated optical device according to claim 1, wherein the second optical waveguide is made of silicon.

3. The semiconductor integrated optical device according to claim 1, wherein the optical waveguide region comprises an upper cladding layer on the silicon oxide layer, the upper cladding layer covers the second optical waveguide, and the upper cladding layer comprises at least one of silicon oxide and benzocyclobutene resin.

4. The semiconductor integrated optical device according to claim 1, wherein the second optical waveguide is exposed.

5. The semiconductor integrated optical device according to claim 1, wherein the silicon oxide layer has a thickness in a range of 1.5 μm to 4 μm.

6. The semiconductor integrated optical device according to claim 1, wherein the semiconductor optical device region comprises a DFB semiconductor laser.

7. The semiconductor integrated optical device according to claim 6, wherein the semiconductor optical device region comprises a plurality of DFB semiconductor lasers, and the DFB semiconductor lasers have different laser emission wavelengths from one another.

8. The semiconductor integrated optical device according to claim 1, wherein the semiconductor optical device region comprises a photodiode structure having a light-absorbing layer.

9. The semiconductor integrated optical device according to claim 1, wherein the optical waveguide region comprises a multi-mode interference coupler which is optically coupled to the second optical waveguide.

10. The semiconductor integrated optical device according to claim 1, wherein the optical waveguide region comprises a wavelength multi/demultiplexer using a Mach-Zehnder interferometer, and the second optical waveguide constitutes the Mach-Zehnder interferometer.

11. A method of making the semiconductor integrated optical device according to claim 1, comprising the steps of:
growing a group III-V compound semiconductor layer on the group III-V compound semiconductor substrate to form the first optical waveguide;
removing a part of the group III-V compound semiconductor layer to provide a space for the optical waveguide region;
depositing the silicon oxide layer in the space by inductively-coupled plasma CVD; and
fondling the second optical waveguide on the silicon oxide layer.

12. The method of claim 11, wherein the silicon oxide layer has a compressive internal stress in a range of 50 MPa to 500 μMPa.
